(19) United States
(12) Patent Application Publication
(10) Pub. No.: US 2009/0236217 A1
(43) Pub. Date: Sep. 24, 2009

(54) CAPILLARITRON ION BEAM SPUTTERING SYSTEM AND THIN FILM PRODUCTION METHOD

(75) Inventors: Liang-chiun Chao, Taipei (TW); Chung-chi Liau, Taipei (TW); Fu-chieh Tsai, Taipei (TW)

Correspondence Address: KIRTON AND MCCONKIE, 60 EAST SOUTH TEMPLE,, SUITE 1800, SALT LAKE CITY, UT, 84111, US

(73) Assignee: National Taiwan University of Science and Technology, Taipei (TW)

(21) Appl. No.: 12/357,592

(22) Filed: Jan. 22, 2009

(30) Foreign Application Priority Data
Mar. 18, 2008 (TW) 097109541

(51) Int. Cl. C23C 14/34

(52) U.S. Cl. 204/192.11; 204/298.04

(57) ABSTRACT

A capillaritron ion beam sputtering system and a thin film production method are disclosed. By utilizing reactive capillaritron ion beam sputtering deposition, argon and oxygen are passed through a capillaritron ion source simultaneously. Argon is being ionized and accelerated by a voltage to bombard a zinc target and create zinc atoms, while oxygen atoms are created at the same time. Zinc atom and oxygen atom are combined to form ZnO to deposit on a substrate. The stoichiometric properties, deposition rate, transmission properties, surface roughness and film density of the as-deposited film can be altered by adjusting capillaritron ion beam energy and oxygen partial pressure. Using preferred processing parameters, the root-mean-square surface roughness of the as-deposited film can be smaller than 1.5 nm, while the transmission coefficient at visible range can be greater than 80%.

### TECHNICAL FIELD OF THE INVENTION

The present invention relates to a sputtering system and a thin film production method, and more particularly, to a capillaritron ion beam sputtering system and a method of reactive capillaritron ion beam sputtering deposition to produce thin films.

### BACKGROUND OF THE INVENTION

In the fields of mechanics, electronics, and semiconductor, thin films are widely used. For example, zinc oxide (ZnO) thin films can be used for transparent conductive films of solar cells, thin-film transistors (TFT) for flat-panel displays, and anti-static conductive films. In addition, ZnO thin films can serve as surface acoustic wave (SAW) devices, gas sensors, and light-emitting devices, etc.

For physical methods to produce thin films, such as vacuum evaporation and sputtering methods, vacuum evaporation has many disadvantages. For example, matters with high melting point are difficult to be evaporated, films are not easy to adhere onto substrates, a film structure is difficult to be reproduced, and thickness of thin films can not be controlled precisely. Generally, sputtering methods are classified into three groups, DC sputtering, RF sputtering, and ion beam sputtering. Please refer to FIG. 1. It shows an exemplary structure diagram of a DC sputtering system and an RF sputtering system. Firstly, the DC sputtering system or the RF sputtering system is maintained at low pressure by pumping air out of a vacuum chamber 101 via an exhaust pipe 151. Gases (such as argon) are introduced into the vacuum chamber 101 via an intake pipe 103. In addition, a target 12 is applied a voltage V₀. A substrate 14 is arranged above a conductor 132. Gases between the target 12 and conductor 132 are plasmanized to form a plasma zone 160. Therefore, ions in the plasma zone 160 are accelerated to bombard the target 12. Sputtered atoms reach the substrate 14 to form a thin film.

However, if the target 12 is not a conductor (e.g., zinc oxide) or the substrate 14 is an insulator, DC sputtering will result in electric charge accumulation. For RF sputtering, AC power supplies are utilized in a range of radio frequencies, for example, 13.56 MHz in industry standard. When applying RF sputtering, a thin film can be produced with any material of conductor, semiconductor, or insulator. But atoms sputtered from the target are likely to collide with background gases and the thin film on the substrate is inevitably impinged by positive ions or negative ions, these factors increase the surface roughness of the thin film. When utilizing DC sputtering or RF sputtering to deposit a ZnO thin film, oxygen and argon in the vacuum chamber 101 are plasmanized as oxygen ions and argon ions in the plasma zone 160. The oxygen ions will impinge the ZnO thin film at a time the argon ions bombard the target 12. As a result, the oxygen ions cause destruction of the ZnO thin film. Moreover, for DC sputtering or RF sputtering, due to properties of plasma, only about 2% energy is used to bombard the target. Furthermore, for semiconductor manufacture, it is necessary to heat the substrate for depositing the ZnO thin film with better quality. After sputtering process, it is necessary to cool the substrate for proceeding photoresist process. This increases time to manufacture the ZnO thin film. Furthermore, a DC power supply employed in DC sputtering, a magnetron sputtering ion gun and an RF power supply employed in RF sputtering, and a vacuum chamber, are expensive and large in size.

Unlike the above-mentioned vacuum evaporation, DC sputtering, and RF sputtering, ion beam sputtering method does not have the aforesaid disadvantages. The ion beam sputtering method uses an ion gun to accelerate ions. These ions bombard the target to sputter atoms of the target and then a thin film is deposited on the substrate. When utilizing the ion beam sputtering method, the thin film is deposited at 10⁻⁴ to 10⁻³ Torr. In this vacuum environment, before reaching the substrate, atoms sputtered from the target have less probability to collide with other atoms than DC sputtering and RF sputtering. Therefore, the thin film fabricated by ion beam sputtering method will result in better quality.

For utilizing the ion beam sputtering method to deposit a metallic oxide, for example, a material of the target such as ZnO is used to deposit a ZnO thin film. Due to different sputtering rates of chemical elements, chemical constituents of the thin film will be different. Therefore, to improve the chemical constituents of the thin film, a metal target can be utilized for depositing the thin film. In the meantime, oxygen is delivered to the vacuum chamber and serves as a background gas. That is, oxygen serves as a reactive gas to react with atoms sputtered from the target. However, for utilizing oxygen as the background gas, due to low probability for oxygen to adhere to the surface of the substrate, a greater amount of oxygen must be utilized.

For the time being, ion guns employed in the ion beam sputtering method are classified into two groups, gated ion guns and un-gated ion guns, respectively developed by United States of America and Former Soviet Union in the 70's. These ion guns were firstly used in artificial satellites to serve as thruster engines, and now are widely used in the semiconductor industry. For gated ion guns, ion guns designed by Harold R. Kaufman are representative ones. A Kaufman ion gun provides electrons with a cathode. If oxygen is utilized, the cathode will be oxidized and injured. Conversely, an un-gated ion gun does not need the cathode to provide electrons. The un-gated ion gun is made up of ferromagnetic material and employed to generate magnetic field. Because iron incorporation of silicon will become a donor, it will damage silicon components. Therefore, semiconductor apparatuses avoid using iron material. Among the ion beam sputtering systems, only reactive gated ion guns are suitable for utilizing reactive gases, for example, oxygen. However, the reactive gated ion guns need to use expensive RF power supplies, which increase cost to manufacture thin films.

Therefore, it is necessary to improve the above-mentioned conventional skills and develop an ion beam sputtering system with lower cost.

### SUMMARY OF THE INVENTION

An objective of the present invention is to provide a sputtering machine with low cost and small size.

Another objective of the present invention is to use reactive ion beam sputtering deposition to produce a zinc oxide (ZnO) thin film.

Another objective of the present invention is to improve the surface roughness of thin films

Another objective of the present invention is to produce thin films at room temperature.

To achieve the above-mentioned objectives, the present invention provides a capillaritron ion beam sputtering system and a thin film production method. The capillaritron ion beam sputtering system of the present invention comprises a capillaritron nozzle, a target, and a substrate. The capillaritron nozzle, introducing gases to pass through, is used for plasmanizing the gases by a voltage for spurting the plasmanized gases to form an ion beam. The target receives the ion beam. A surface of the target is bombarded by the ion beam to sputter particles of the target. The substrate receives the particles sputtered from the surface of the target to deposit a thin film.

The thin film production method of the present invention comprises steps of: introducing a bombarding gas to pass through a capillaritron nozzle; plasmanizing the bombarding gas by a voltage applied to the capillaritron nozzle for spurting the plasmanized bombarding gas to form an ion beam; bombarding a target with the ion beam to sputter particles in a surface of the target; and depositing a thin film onto a substrate by receiving the particles sputtered from the surface of the target.

The thin film can be produced by reactive capillaritron ion beam sputtering deposition. The thin film production method of the present invention comprises steps of: introducing a bombarding gas and a reactive gas to pass through a capillaritron nozzle at the same time; plasmanizing the bombarding gas and reactive gas by a voltage applied to the capillaritron nozzle for spurting the plasmanized bombarding gas and reactive gas to form an ion beam; bombarding a target with the ion beam to sputter particles in a surface of the target; utilizing the reactive gas to react with the particles sputtered from the surface of the target; and depositing a thin film onto a substrate by receiving reaction products of the reactive gas and the sputtered particles. For example, the bombarding gas and reactive gas are argon and oxygen respectively, and a material of the target is zinc, then the thin film deposited onto the substrate is a ZnO thin film.

Unlike the conventional skills, the reactive gas of the present invention is delivered to a vacuum chamber with the bombarding gas via the capillaritron nozzle while the reactive gas in the conventional skills serve as a background gas in the vacuum chamber. To improve the chemical constituents of thin films, a great amount of reactive gas must be employed and introduced into the chamber in the conventional skills. However, the present invention only needs to maintain the flow rate of reactive gas, rather than to use a great amount of reactive gas, to produce thin films with desired chemical constituents and stable quality.

The capillaritron ion beam sputtering system of the present invention can utilize targets with various kinds of materials. The material of the target may constitute a part or all of the thin film deposited on the substrate. Applying the thin film production method of the present invention can produce various kinds of thin films. For example, a ZnO thin film. The root-mean-square surface roughness of produced ZnO thin film according to the present invention is smaller than about 1.5 nm. Moreover, the root-mean-square surface roughness of the preferred ZnO thin film according to the present invention can be smaller than about 0.6 nm. The transmission coefficient at visible range can be greater than 80%.

The ion beam of the present invention is generated by a capillaritron ion source. The ion beam bombards the target to sputter particles (or atoms) of the target. The effect of reflected ion beam momentum on the surface roughness of thin films can be reduced by arranging the substrate away from the target. However, for DC sputtering or RF sputtering, since positive ions and negative ions are in the plasma zone, the thin film on the substrate is inevitably bombarded by these ions. This affects the surface roughness of the thin film.

The structure of ion source of the present invention is much simpler than DC sputtering or RF sputtering. The sputtering system of the present invention has advantages of low cost and small size, and can be designed into a small sputtering machine. Furthermore, thin films can be fabricated at room temperature without heating the substrate. For semiconductor manufacture, the present invention can reduce time for cooling the substrate. However, heating the substrate of the sputtering system according to the present invention can also increase the movement of atoms of the substrate and improve the quality of thin films further.

The present invention employs a capillaritron ion gun to serve as an ion source of the ion beam sputtering system. Compared with a conventional gated ion gun, the capillaritron ion gun does not need to provide electrons with a cathode. Therefore, the cathode is hard to be oxidized and injured. Unlike a conventional un-gated ion gun, the capillaritron ion gun does not need to be manufactured with ferromagnetic material. Accordingly, in the semiconductor process, the present invention will not cause silicon components to be damaged. Compared with a conventional reactive gated ion gun, the capillaritron ion beam sputtering system of the present invention does not need to use expensive an RF power supply. Only a cheaper DC power supply is essential to generate plasma and accelerate ions. In conclusion, the capillaritron ion beam sputtering system of the present invention has many advantages, such as low cost to manufacture thin films, the sputtering system being small in size and simpler, controlling the density of ion current precisely, and suitable for using reactive gases.

### BRIEF DESCRIPTION OF THE DRAWINGS

FIG. 1 shows an exemplary structure diagram of conventional DC sputtering system and RF sputtering system.

FIG. 2 shows an exemplary structure diagram of a capillaritron ion beam sputtering system according to the present invention.

FIG. 3 shows a graph of He—Cd photoluminescence (PL) excitation (as 325 nm) for a ZnO film deposited on a substrate according to the present invention.

FIG. 4 is a graph depicting X-ray diffraction (XRD) pattern of a ZnO film deposited on a substrate according to the present invention.

FIG. 5 is a graph depicting relation curves between the root-mean-square surface roughness of ZnO films and oxygen flux in the second embodiment and third embodiment according to the present invention.

FIG. 6a and FIG. 6b respectively show relation curves between the atomic percent ratio of Zn/O and oxygen flux in the second embodiment and third embodiment, where ZnO thin films are analyzed by x-ray photoelectron spectroscopy (XPS).

FIG. 7 is a graph depicting a relation curve between refractive index and oxygen flux in the third embodiment according to the present invention.

FIG. 8 is a graph depicting transmission properties of ZnO thin films in the third embodiment according to the present invention.

FIG. 9 is a graph depicting band gaps of ZnO thin films in the third embodiment according to the present invention.

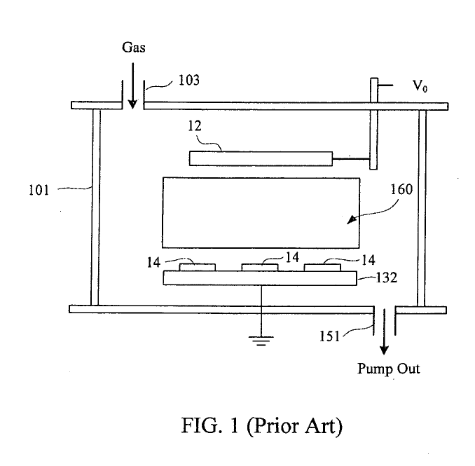

### DETAILED DESCRIPTION OF THE INVENTION

The present invention will be described in details in conjunction with the appending drawings.

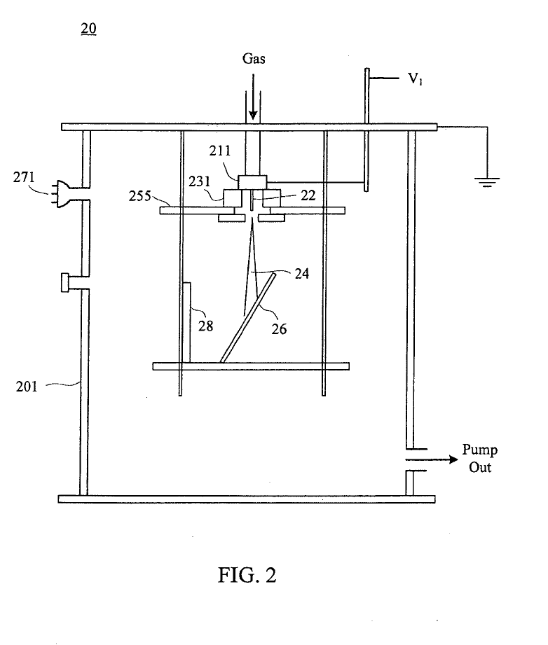

Please refer to FIG. 2, which shows a structure diagram of a capillaritron ion beam sputtering system 20 according to the present invention. The capillaritron ion beam sputtering system 20 is maintained at low pressure by pumping air out of a vacuum chamber 201. In addition, an ion gauge 271 is employed to measure and indicate the level of vacuum in the sputtering system 20. The ion source utilized in the sputtering system 20 of the present invention has a capillaritron nozzle 22. A conductor 211 applied a voltage V₁ is arranged at an inlet side of the capillaritron nozzle 22. A conductor 255 connected to the body of vacuum chamber 201 is arranged at an outlet side of the capillaritron nozzle 22. An insulator 231 is arranged between the inlet side and outlet side of the capillaritron nozzle 22. Since the body of vacuum chamber 201 is grounded, a voltage potential is applied to the capillaritron nozzle 22. Therefore, gases passing through the capillaritron nozzle 22 are plasmanized and can be accelerated by the electric field generated due to the voltage potential. The plasmanized gases are spurted to form an ion beam 24. The ion beam 24 bombards a surface of the target 26 to spurt particles in the surface of the target 26. The sputtered particles reach the substrate 28. Accordingly, a thin film is deposited onto the substrate 28. Moreover, the capillaritron nozzle 22, and target 26 can be treated as a sputtering source. An ion beam ejected from the sputtering source mainly consists of material particles of target. A target replaceable sputtering source can also be employed as the sputtering source. Therefore, it is convenient to utilize different materials of targets to deposit films.

The capillaritron ion beam sputtering system 20 provided by the present invention can utilize targets with various kinds of materials. For example, metal, nonmetal, conductor, semiconductor, or insulator materials can be illustrated. Chemical constituents of the film deposited on the substrate 28 can be related with a material of the target 26. In addition, for reactive sputtering, the film deposited on the substrate 28 also has relations with a background gas in the vacuum chamber 201 or a gas passing through the capillaritron nozzle 22.

The present invention provides a thin film production method. The method will be described by the following steps: introducing a bombarding gas to pass through the capillaritron nozzle 22; plasmanizing the bombarding gas by a voltage applied to the capillaritron nozzle 22 for spurting the plasmanized bombarding gas to form the ion beam 24; bombarding the target 26 with the ion beam 24, which is comprised of the plasmanized bombarding gas, to sputter particles in a surface of the target 26; and depositing a thin film onto the substrate 28 by receiving the particles sputtered from the surface of the target 26.

The present invention also provides a method of reactive capillaritron ion beam sputtering deposition to produce thin films. The method will be described by the following steps: introducing a bombarding gas and a reactive gas to pass through the capillaritron nozzle 22 at the same time; plasmanizing the bombarding gas and reactive gas by a voltage applied to the capillaritron nozzle 22 for spurting the plasmanized bombarding gas and reactive gas to form the ion beam 24; bombarding the target 26 with the ion beam 24, which is comprised of the bombarding gas and reactive gas, to sputter particles in a surface of the target 26; utilizing the reactive gas to react with the particles sputtered from the surface of the target 26; and depositing a thin film onto the substrate 28 by receiving reaction products of the reactive gas and the sputtered particles. In addition, argon may serve as the bombarding gas. Argon ions are used to bombard the target 26. If the reactive gas is oxygen and the target 26 is metal, a metallic oxide (e.g., zinc oxide or alumina) thin film will be deposited on the substrate 28. If the reactive gas is nitrogen and the target 26 is metal, a metallic nitride (e.g., aluminum nitride or gallium nitride) thin film will be deposited on the substrate 28.

Applying the capillaritron ion beam sputtering system and thin film production method of the present invention, three embodiments to produce zinc oxide (ZnO) thin films will be described in details in conjunction with experimental results and data in the following paragraphs.

In a first embodiment, an ion beam directly impinges on a ZnO target, and then a ZnO thin film is deposited onto a substrate. In a second embodiment, oxygen (not plasmanized by a capillaritron ion source) is introduced in a vacuum chamber to serve as a background gas. An ion beam bombards a Zn target to sputter zinc atoms. The sputtered zinc atoms react with the background oxygen gas, and then a ZnO thin film is deposited onto a substrate. In a third embodiment, argon and oxygen pass through a capillaritron ion source to be plasmanized at the same time. Both the plasmanized argon and oxygen can be used to bombard a Zn target to sputter zinc atoms. The sputtered zinc atoms react with the plasmanized oxygen, and then a ZnO thin film is deposited onto a substrate.

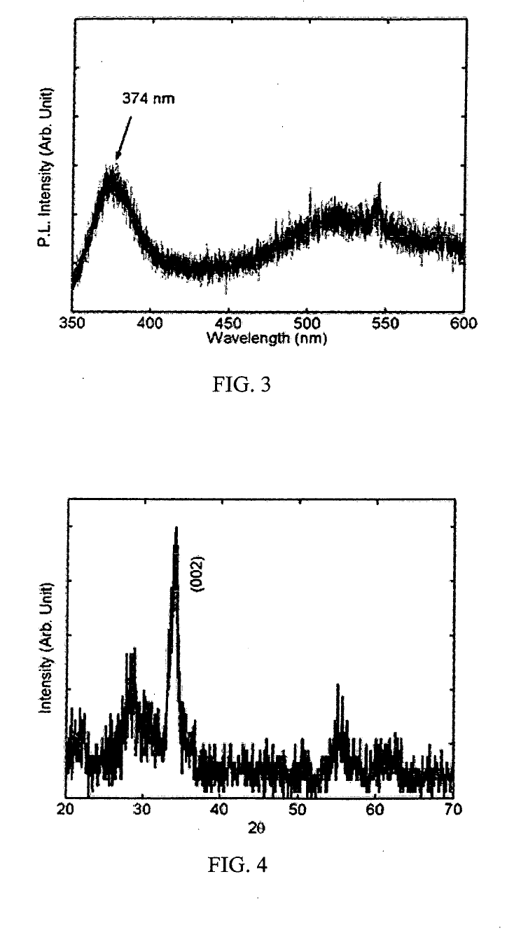

The stoichiometric properties, deposition rate, transmission properties, surface roughness and film density of the as-deposited ZnO film in the third embodiment can be altered by adjusting capillaritron ion beam energy and oxygen partial pressure. Please refer to FIG. 3. It depicts He—Cd photoluminescence (PL) excitation (as 325 nm) for the as-deposited ZnO film, which is deposited at 4 mTorr working pressure, 7 sccm (standard cubic centimeters per minute) argon flux, and 0.6 sccm oxygen flux. The PL spectrum shown in FIG. 3 indicates a strong emission line at 374 nm. It confirms that the as-deposited film is indeed a ZnO film. FIG. 4 is a graph depicting X-ray diffraction (XRD) pattern of the as-deposited ZnO film. Since a diffraction peak (002) is found, it reveals that the as-deposited ZnO film grows in the (002) crystallographic direction.

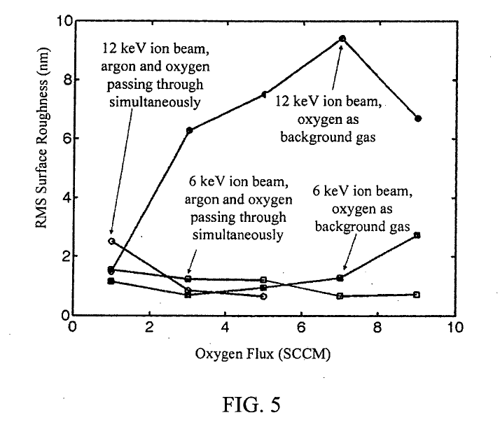

Please refer to FIG. 5. The second embodiment (oxygen serving as background gas) and the third embodiment (argon and oxygen passing through the capillaritron ion source simultaneously) are compared to study effect of oxygen flux on the root-mean-square surface roughness of ZnO film. If oxygen serves as background gas, and energy of ion beam is 6 keV and 12 keV respectively, the root-mean-square surface roughness scanned by atomic force microscope (AFM) increases as oxygen flux increases. If argon and oxygen pass through the capillaritron ion source simultaneously, the root-mean-square surface roughness decreases as oxygen flux increases. This is because oxygen particles gradually become main particles to bombard the target since an oxygen atom is lighter than an argon atom. When accelerated by the same voltage, oxygen particles have lower kinetic energy than argon particles. When oxygen particles become main particles to bombard the Zn target, energy transformation between oxygen particles and zinc particles, results in lower energy of zinc particles. Therefore, since particles or chemical compounds sputtered onto the substrate have much lower energy, they have less influence on the root-mean-square surface roughness of the thin film. As shown in FIG. 5, if argon and oxygen pass through the capillaritron ion source simultaneously, and energy of ion beam is 6 keV, the root-mean-square surface roughness of fabricated ZnO thin film is smaller than about 1.5 nm. Moreover, the root-mean-square surface roughness of preferred ZnO thin film can be smaller than about 0.6 nm.

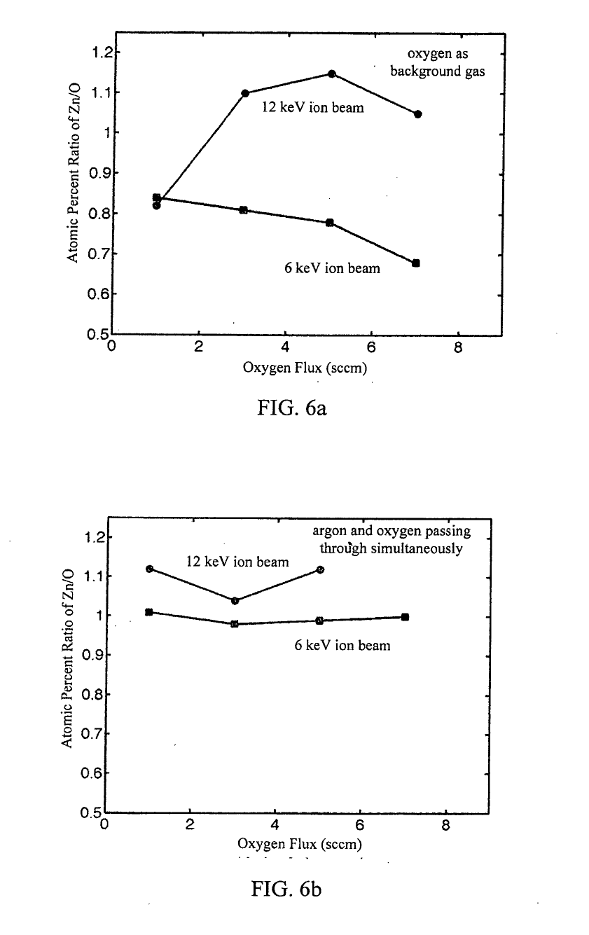

FIG. 6a and FIG. 6b show relation curves between the atomic percent ratio of Zn/O and oxygen flux in the second embodiment (oxygen serving as background gas) and the third embodiment (argon and oxygen passing through the capillaritron ion source simultaneously), 6 keV and 12 keV ion beam, respectively. The ZnO thin films are analyzed by x-ray photoelectron spectroscopy (XPS). As shown in FIG. 6a and FIG. 6b, for ZnO thin films fabricated in the second embodiment, their variations of atomic percent ratio of Zn/O are greater than the third embodiment. As shown in FIG. 6b, for ZnO thin films fabricated in the third embodiment, 6 keV ion beam, each atomic percent ratio of Zn/O is 1.0. The atomic percent ratio of Zn/O in the third embodiment is hardly influenced by oxygen flux.

Among all afore-mentioned embodiments, ZnO thin films fabricated in the third embodiment have much better quality and stable chemical constituents. Moreover, 6 keV ion beam is preferred in the third embodiment.

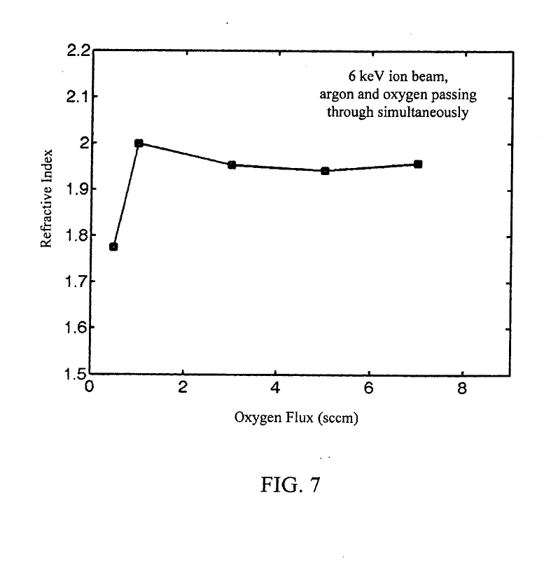

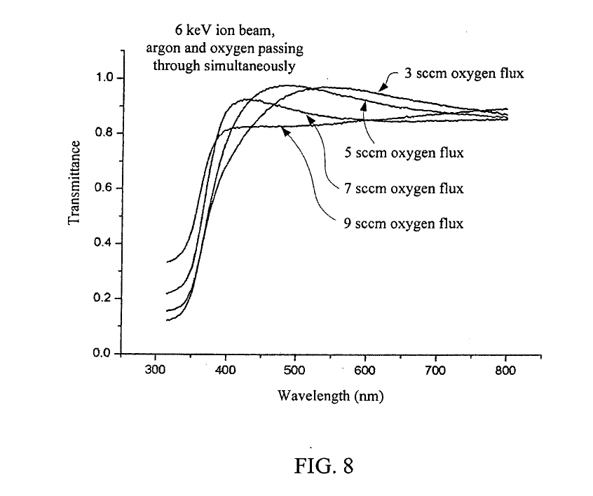

FIG. 7 shows a relation curve between refractive index and oxygen flux in the third embodiment (argon and oxygen passing through the capillaritron ion source simultaneously), 6 keV ion beam. The ZnO thin films are fabricated with oxygen flux of 0.5, 1, 5, and 7 sccm. The refractive index of ZnO thin films fabricated with oxygen flux above 1.0 sccm is more stable. FIG. 8 shows transmission properties of ZnO thin films in the third embodiment, 6 keV ion beam. The ZnO thin films deposited on quartz substrates are fabricated with oxygen flux of 3, 5, 7, and 9 sccm. The transmission coefficient at visible range (approximately in a range of 400 to 700 nm) can be greater than 80%. According to the present invention, the ZnO thin films by using argon and oxygen to pass through the capillaritron ion source simultaneously have better quality and are more stable.

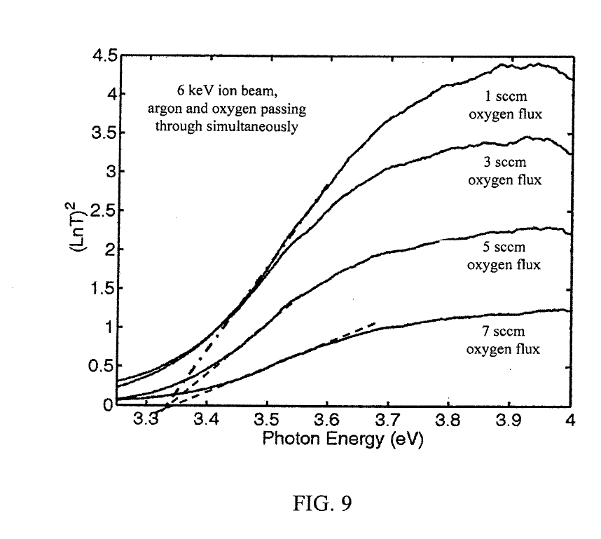

FIG. 9 shows band gaps of ZnO thin films by using argon and oxygen to simultaneously pass through the capillaritron ion source in the third embodiment, 6 keV ion beam. The ZnO thin films are fabricated with oxygen flux of 3, 5, 7, and 9 sccm. As shown in FIG. 9, the band gaps of the ZnO thin films are all 3.3 eV approximately.

For all afore-mentioned embodiments, ZnO thin films are fabricated at room temperature. In addition, there is no need to heat the substrate. But heating the substrate can increase the movement of atoms of the substrate and thus improve the quality of ZnO thin films.

The capillaritron ion beam sputtering system of the present invention has advantages of low cost and small size. The aforesaid sputtering system can be designed into a small sputtering machine. In addition, the capillaritron ion beam sputtering system of the present invention can efficiently improve the surface roughness of thin films.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A capillaritron ion beam sputtering system, the system comprising:
a capillaritron nozzle, introducing at least one type of gas plasmanized by a voltage therethrough for spurting the gas plasmanized to form an ion beam;
a target, for receiving the ion beam, a surface of the target being bombarded by the ion beam to sputter particles of the target; and
a substrate, for receiving the particles sputtered from the surface of the target to deposit a thin film.

2. The system of claim 1, wherein a material of the target is zinc oxide (ZnO), and the deposited film is a ZnO thin film.

3. The system of claim 1, wherein oxygen gas serves as a background gas in a chamber, a material of the target is zinc, and the thin film deposited onto the substrate is a ZnO thin film.

4. The system of claim 1, wherein the at least one type of gas comprises a bombarding gas, which is plasmanized for bombarding the surface of the target to sputter the particles.

5. The system of claim 1, wherein the at least one type of gas comprises a reactive gas, which is plasmanized for reacting with the particles sputtered from the surface of the target.

6. The system of claim 5, wherein oxygen gas serves as the reactive gas, a material of the target is zinc, and the thin film deposited onto the substrate is a ZnO thin film.

7. The system of claim 6, wherein the energy of the ion beam lies between 5 and 7 keV.

8. The system of claim 6, wherein a root-mean-square surface roughness of the ZnO thin film is smaller than 1.5 nm.

9. The system of claim 6, wherein transmission coefficient of the ZnO thin film at visible range is greater than 80%.

10. The system of claim 5, wherein oxygen gas serves as the reactive gas, a material of the target is aluminum, and the thin film deposited onto the substrate is an alumina thin film.

11. A thin film production method, the method comprising:
introducing at least one type of gas to pass through a capillaritron nozzle;
plasmanizing the gas by a voltage applied to the capillaritron nozzle for spurting the plasmanized gas to form an ion beam;
bombarding a target with the ion beam to sputter particles in a surface of the target; and
depositing a thin film onto a substrate by receiving the particles sputtered from the surface of the target.

12. The method of claim 11, wherein a material of the target is zinc oxide (ZnO), and the thin film deposited onto the substrate is a ZnO thin film.

13. The method of claim 11 further comprising a step of introducing oxygen gas to serve as a background gas in a chamber, wherein a material of the target is zinc, and the thin film deposited onto the substrate is a ZnO thin film.

14. The method of claim 11, wherein the at least one type of gas comprises a bombarding gas, which is plasmanized for bombarding the surface of the target to sputter the particles.

15. The method of claim 11, wherein the at least one type of gas comprises a reactive gas, which is plasmanized for reacting with the particles sputtered from the surface of the target.

16. The method of claim 15, wherein oxygen gas serves as the reactive gas, a material of the target is zinc, and the thin film deposited onto the substrate is a ZnO thin film.

17. The method of claim 16, wherein the energy of the ion beam lies between 5 and 7 keV.

18. The method of claim 16, wherein a root-mean-square surface roughness of the ZnO thin film is smaller than 1.5 nm.

19. The method of claim 15, wherein nitrogen gas serves as the reactive gas, a material of the target is aluminum, and the thin film deposited onto the substrate is a aluminum nitride thin film.
